(19) United States
(12) Patent Application Publication
(10) Pub. No.: US 2012/0241932 A1
(43) Pub. Date: Sep. 27, 2012

(54) SEMICONDUCTOR DEVICE

(75) Inventor: Yoshiaki GOTO, Kiyosu-Shi (JP)

(73) Assignee: Kabushiki Kaisha Toshiba, Tokyo (JP)

(21) Appl. No.: 13/231,039

(22) Filed: Sep. 13, 2011

(30) Foreign Application Priority Data
Mar. 25, 2011 (JP) 2011-068687

(51) Int. Cl. H01L 23/495

(52) U.S. Cl. 257/676; 257/E23.052

(57) ABSTRACT

A semiconductor device according to the embodiment is provided with an inner lead. The inner lead includes a first surface and a second surface opposite thereto. A semiconductor chip is mounted on the first surface. A first resin portion seals the semiconductor chip on the first surface. A second resin portion is provided on the second surface. An outer lead is connected to the inner lead, and configured to project outside from the first and second resin portions. A width of the second resin portion in a first direction where the outer lead projects is smaller than that of the first resin portion in the first direction.

### CROSS REFERENCE TO RELATED APPLICATIONS

This application is based upon and claims the benefit of priority from the prior Japanese Patent Application No. 2011-68687, filed on Mar. 25, 2011, the entire contents of which are incorporated herein by reference.

### FIELD

The embodiment of the present invention relates to a semiconductor device.

### BACKGROUND

Conventionally, thin small outline packages (TSOPs) have been generally used as semiconductor packages. The TSOP is a thin package made by sealing with mold resin a semiconductor chip, an inner lead, a gold wire, etc. In a case of a chip on lead (COL) type TSOP having a semiconductor chip mounted on a bottom surface of the inner lead, there is no problem to achieve an object of the mold resin to protect the semiconductor chip, the gold wire, etc. even if a top surface of the inner lead not having the semiconductor chip mounted thereon (hereinafter referred to as a non-mounting surface) is exposed.

However, when the mold resin on the non-mounting surface is made thin, in a case where an outer lead is bent upward (to a non-mounting surface side), an end of the inner lead connected to the outer lead is lifted with the outer lead. As a result of this, there is a possibility that the mold resin of the non-mounting surface side of the end of the inner lead is chipped.

In addition, usually, a thickness of mold resin provided on the non-mounting surface is smaller than that of mold resin that covers the semiconductor chip of the semiconductor chip mounting surface. This is because a gap between a molding die with which a gold wire need to be covered and the semiconductor chip is larger than a gap between a molding die with which the gold wire need not be covered and the non-mounting surface. In this case, when resin seal is performed with a transfer mold method, filling of resin at a mounting surface side becomes faster than that of resin at the non-mounting surface side. When a difference between filling speeds of resin is large, a force acts with which the resin of the mounting surface side with a fast filling speed pushes the inner lead to the non-mounting surface side with a slow filling speed during implementation of the transfer mold method. Accordingly, the force moves the semiconductor chip while deforming the inner lead to the non-mounting surface side. When the resin deforms the inner lead to the non-mounting surface side, the gap between the molding die and the non-mounting surface becomes smaller. As a result of this, there is a possibility that the inner lead or the semiconductor chip is exposed since the resin does not fully spread over the non-mounting surface side. This leads to an appearance defect.

### BRIEF DESCRIPTION OF THE DRAWINGS

FIG. 1A is a plan view of a semiconductor device 10 according to a first embodiment;

FIG. 1B is a cross-sectional view of the semiconductor device 10 taken along a line B-B of FIG. 1A;

FIG. 2 is an enlarged cross-sectional view of the step 13 and the surrounding portions of FIG. 1B;

FIG. 3 is a plan view showing one example of a configuration of the inner lead 4a;

FIG. 4 is a plan view showing another example of a configuration of the inner lead 4a;

FIGS. 5A to 5C are cross-sectional views showing a modified example of a shape of the anchor hole 9; and

FIG. 6 is a view showing a structure made by stacking a plurality of semiconductor devices 10 according to the embodiment.

### DETAILED DESCRIPTION

A semiconductor device according to the embodiment is provided an inner lead. The inner lead includes a first surface and a second surface opposite thereto. A semiconductor chip is mounted on the first surface. A first resin portion seals the semiconductor chip on the first surface. A second resin portion is provided on the second surface. An outer lead is connected to the inner lead, and configured to project outside from the first and second resin portions. A width of the second resin portion in a first direction where the outer lead projects is smaller than that of the first resin portion in the first direction.

Embodiments will now be explained with reference to the accompanying drawings.

### First Embodiment

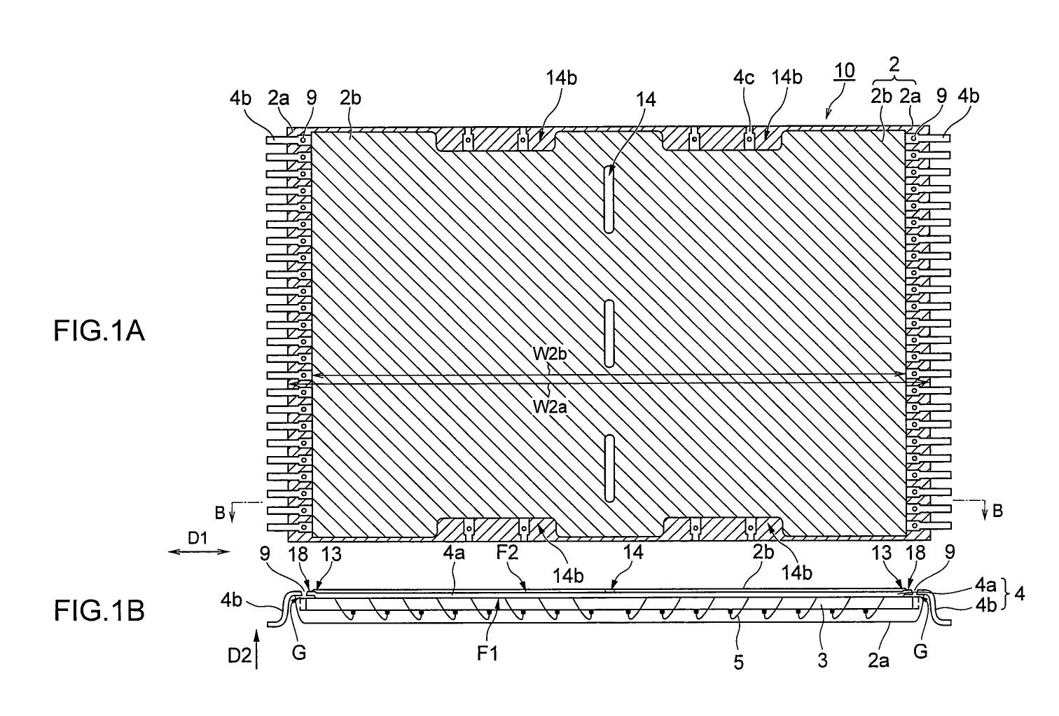

FIG. 1A is a plan view of a semiconductor device 10 according to a first embodiment. FIG. 1B is a cross-sectional view of the semiconductor device 10 taken along a line B-B of FIG. 1A. Note that FIG. 1A is the plan view viewed from an upper side of a non-mounting surface F2 shown in FIG. 1B. The semiconductor device 10 is provided with a sealing resin 2, a semiconductor chip 3, a lead 4, and a metal wire 5.

The lead 4 includes an inner lead 4a and an outer lead 4b. The inner lead 4a is a lead portion sealed or covered with the sealing resin 2 within the lead 4, and the outer lead 4b is a lead portion that is exposed from the sealing resin 2 and that projects to an outside of the sealing resin 2 from the inner lead 4a within the lead 4. One semiconductor device 10 is provided with a plurality of leads 4 electrically insulated from each other, and the leads 4 include the inner lead 4a and the outer lead 4b, respectively. The inner lead 4a and the outer lead 4b are integrally formed as the lead 4. A conductive material (for example, metal) is used for the lead 4.

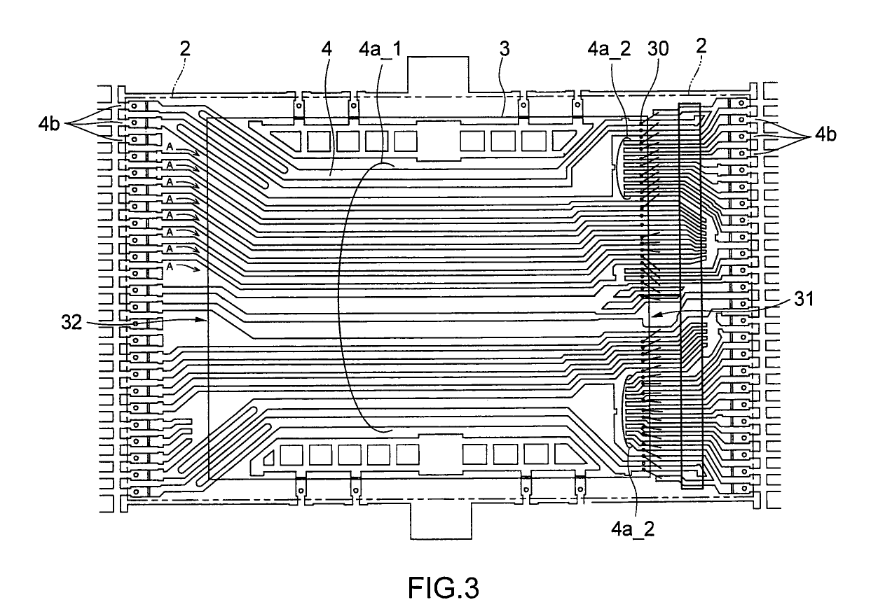

The inner lead 4a is electrically connected to a bonding pad 30 (refer to FIG. 3) of the semiconductor chip 3 through the metal wire 5. The outer lead 4b is electrically connected to the bonding pad 30 of the semiconductor chip 3 through the inner lead 4a and the metal wire 5. The lead 4 enables data or a command from an outside of the semiconductor device 10 to be transmitted to the semiconductor chip 3 inside the semiconductor device 10, and conversely, enables data from the semiconductor chip 3 to be transmitted to the outside of the semiconductor device 10.

The inner lead 4a is also provided with a function as a mounting portion to mount the semiconductor chip 3 thereon. The outer lead 4b is formed as a gull-wing shape so as to bend toward a mounting surface (first surface) F1 side having the semiconductor chip 3 mounted thereon. As a result of this, the semiconductor device 10 according to the embodiment constitutes a COL type TSOP.

A first resin portion 2a of the sealing resin 2 is provided on the mounting surface (first surface) F1 of the inner lead 4a having the semiconductor chip 3 mounted thereon and between the inner leads 4a. The first resin portion 2a seals the semiconductor chip 3 and the metal wire 5 to thereby protect them. A second resin portion 2b of the sealing resin 2 is provided on the non-mounting surface (second surface) F2 of the inner lead 4a not having the semiconductor chip 3 mounted thereon. Since the second resin portion 2b does not seal the semiconductor chip 3, the metal wire 5, etc., it is formed thinner than the first resin portion 2a.

The lead 4 is provided with an anchor hole 9 and a step 13 at a boundary portion 18 between the inner lead 4a and the outer lead 4b. The anchor hole 9 is the hole that is covered with the first resin portion 2a in the mounting surface F1 of the inner lead 4a, and that is exposed from the second resin portion 2b in the non-mounting surface F2 of the inner lead 4a. The step 13 is the step formed by depress-processing the lead 4 by a forming die.

The anchor hole 9 is provided so as to penetrate the inner lead 4a. The anchor hole 9 is opened so as to widen from the mounting surface F1 toward the non-mounting surface F2 of the inner lead 4a, and the first resin portion 2a is embedded in the anchor hole 9. Namely, the anchor hole 9 has a taper on an inner wall surface thereof, and it is formed so that an opening diameter of the non-mounting surface side of the inner lead 4a is bigger than that of the mounting surface side of the inner lead 4a. As a result of this, even though a stress in a direction D2 from the mounting surface F1 to the non-mounting surface F2 of the inner lead 4a is applied to the outer lead 4b, outer lead 4b can be suppressed from separating from the first resin portion 2a. Namely, even though the outer lead 4b is pushed up in a D2 direction, the anchor hole 9 functions as a retaining hole for the first resin portion 2a, and thus the first resin portion 2a can be suppressed from coming away from the anchor hole 9.

The step 13 is provided so that the outer lead 4b protrudes closer to the non-mounting surface F2 side than the inner lead 4a in the boundary portion 18 between the outer lead 4b and the inner lead 4a. Hereinafter, the boundary portion 18 between the outer lead 4b and the inner lead 4a is referred to as a protruding portion 18. In a resin sealing process, since the protruding portion 18 gets contact with a molding die for resin seal (not shown), the second resin portion 2b does not cover the protruding portion 18. Since the second resin portion 2b is not provided on the protruding portion 18, there is little possibility that an end of the second resin portion 2b is chipped even if the first resin portion 2a comes away from the anchor hole 9.

In addition, even though resin of the mounting surface side with a fast filling speed pushes the inner lead to the non-mounting surface side during the resin sealing process, a gap can be maintained between the non-mounting surface F2 of the inner lead 4 and the molding die thereof by a height of the step 13 and by a cavity depth of the mold from the protruding portion 18 of the inner lead 4a since the protruding portion 18 gets contact with the molding die for resin seal. Accordingly, the sealing resin easily enters a space of the non-mounting surface F2 side, and thus the non-mounting surface F2 of the inner lead 4a can be fully covered with the second resin portion 2b. As a result of this, the inner lead 4a and the semiconductor chip 3 are not exposed, and thus occurrence of an appearance defect can be suppressed. As described above, the semiconductor device according to the embodiment can suppress attachment of the second resin portion 2b to the protruding portion 18 between the outer lead 4b and the inner lead 4a while fully covering the non-mounting surface F2 of the inner lead 4a with the second resin portion 2b.

Further, the anchor hole 9 is provided in the protruding portion 18 of the lead 4 and hanging pin 4c around a dent 14b. Moreover, as shown in FIGS. 1A and 1B, a width W2b of the second resin portion 2b is smaller than a width W2a of the first resin portion 2a in a first direction D1 where the outer lead 4b projects. As a result of this, the anchor hole 9 is not covered with the second resin portion 2b at the non-mounting surface F2 side of the inner lead 4a, and it is covered with the first resin portion 2a at the mounting surface F1 side of the inner lead 4a. In addition, an inside of the anchor hole 9 is filled with the first resin portion 2a from the mounting surface F1 side. As a result of this, as mentioned above, the anchor hole 9 functions as the retaining hole for the first resin portion 2a in the protruding portion 18, and even if the first resin portion 2a comes away from the anchor hole 9, a possibility that the second resin portion 2b is chipped can be reduced since there is no second resin portion 2b on the protruding portion 18.

Further, the step 13 suppresses the semiconductor chip 3 from blocking the anchor hole 9 at the mounting surface F1 side of the inner lead 4a. As shown with a dashed line of FIG. 1B, when the semiconductor chip 3 exists on the anchor hole 9, the semiconductor chip 3 blocks an opening of the mounting surface F1 side of the anchor hole 9 without the step 13. In this case, the inside of the anchor hole 9 is not filled with the resin 2, and the anchor hole 9 cannot serve as the retaining hole. In the embodiment, the step 13 is provided with a gap G between the semiconductor chip 3 and the opening of the mounting surface F1 side of the anchor hole 9. This gap G allows the resin 2 to enter the anchor hole 9, and it becomes possible for the anchor hole 9 to serve as the retaining hole. After completion of the semiconductor device 10, the resin 2 exists in this gap G.

A dent 14 is provided on a part of the second resin portion 2b of the inner lead 4a. The dent 14 is the dent that has remained in the semiconductor device 10 as a mark of a projection provided in the molding die in the resin sealing process. The dent 14 is not provided with the second resin portion 2b. Alternatively, even though the second resin portion 2b exists in the dent 14, a thickness of the second resin portion 2b of the dent 14 is smaller compared with that of the second resin portion 2b of the non-mounting surface F2 except the dent 14. The reason why the dent 14 is formed is as follows. When resin seal is performed using a transfer mold method, the resin 2 flows into the mounting surface F1 side faster than into the non-mounting surface F2 side since the gap between the molding die for resin seal and the mounting surface F1 is larger than the gap between the molding die and the non-mounting surface F2. At this time, there is a case where a force of pushing the inner lead 4a to the non-mounting surface F2 side acts to the resin 2.

In the embodiment, the molding die is provided with the projection in contact with at least a part of the non-mounting surface F2 of the inner lead 4a in order to secure the gap between the molding die and the non-mounting surface F2. The protruding portion 18 gets contact with the molding die, and also the projection of this molding die gets contact with the non-mounting surface F2 of the inner lead 4a, whereby the gap between the molding die and the non-mounting surface F2 can be secured. As a result of this, even though the resin 2 pushes the inner lead 4a to the non-mounting surface F2 side, the resin 2 can be fully flowed also into the non-mounting surface F2 side. For the above-described reason, the dent 14 is formed.

A position of the dent 14 is determined according to a position of the projection of the molding die. The position of the dent 14 may be a center of the semiconductor device 10, or the dent 14 may be provided at a position displaced from the center thereof. However, it is preferable that the dents 14 are equally arranged within the non-mounting surface F2 of the inner lead 4a in order to substantially uniform the thickness of the second resin portion 2b.

Note that the inner lead 4a is exposed in the dent 14. However, the non-mounting surface of the inner lead 4a exists at a lower position (mounting surface F1 side) than a surface of the second resin portion 2b. Hence, there is little possibility that the inner lead 4a gets contact with a conductive body around the semiconductor device 10.

Only one semiconductor chip 3 is shown in FIG. 1B. However, a plurality of semiconductor chips 3 may be stacked in one semiconductor device 10. The number of stacked semiconductor chips 3 is not limited. The semiconductor chip 3 may be, for example, a NAND type flash memory. Naturally, the semiconductor chip 3 is not limited to the NAND type flash memory, but the other IC chips may be used. A gold wire is used for the metal wire 5, for example.

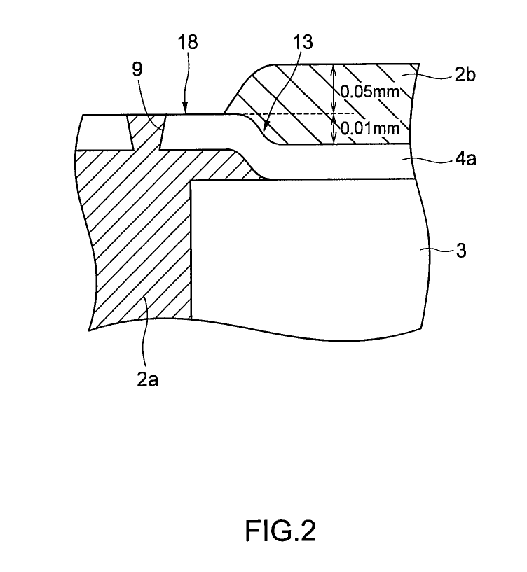

FIG. 2 is an enlarged cross-sectional view of the step 13 and the surrounding portions of FIG. 1B. With reference to FIG. 2, will be described a specific example of a thickness of each element or a gap of the semiconductor device according to the embodiment.

Depending on a material of the resin 2, generally, a gap of at least 0.06 millimeter is needed to pour the resin 2 thereinto. Hence, when a distance in a direction D2 between a surface of the protruding portion 18 of the lead 4 and an inner wall of the molding die (upper die) of the non-mounting surface F2 side is, for example, set to be 0.05 millimeter, a height of the step 13 only has to be 0.01 millimeter. As a result of this, the resin 2 can be poured into the non-mounting surface F2 side of the inner lead 4a.

When considering a manufacturing margin and a range of selection of a filler included in the mold resin, the distance in a direction D2 between the surface of the protruding portion 18 of the lead 4 and the inner wall of the molding die (upper die) of the non-mounting surface F2 side is, for example, 0.05 millimeter. The height of the step 13 is, for example, 0.05 millimeter.

The first resin portion 2a need to have at least a thickness of 0.2 millimeter from a surface having the bonding pad 30 provided thereon of the semiconductor chip 3 so that the metal wire 5 is not exposed from the first resin portion 2a. When a thickness of the semiconductor chip 3 and a thickness of adhesive (not shown) that fixes the semiconductor chip 3 and the inner lead 4a are totally set to be 0.4 millimeter, a thickness of the whole first resin portion 2a is a total of 0.6 millimeter.

Consequently, when setting a thickness of the inner lead 4a to be 0.1 millimeter, the distance in a direction D2 between the surface of the protruding portion 18 of the lead 4 and the inner wall of the upper mold to be 0.05 millimeter, the height of the step 13 to be 0.05 millimeter, and the thickness of the first resin portion 2a to be 0.6 millimeter, a thickness of the TSOP according to the embodiment is 0.8 millimeter.

FIG. 3 is a plan view showing one example of a configuration of the inner lead 4a. The plurality of inner leads 4a is electrically connected to the bonding pad 30 of the semiconductor chip 3. The bonding pad 30 is collectively formed on one side portion 31 of the semiconductor chip 3. An inner lead 4a_1, which is a part of the plurality of inner leads 4a, extends toward a side portion 32 different from the side portion 31 having the bonding pad 30 provided thereon of the semiconductor chip 3. Additionally, the inner lead 4a_1 is connected to the outer lead 4b projecting from a side portion 32 side to an outside of the resin 2.

Another inner lead 4a_2 of the plurality of inner leads 4a is connected to the outer lead 4b projecting to the outside of the resin 2 from the side portion 31 having the bonding pad 30 provided thereon of the semiconductor chip 3.

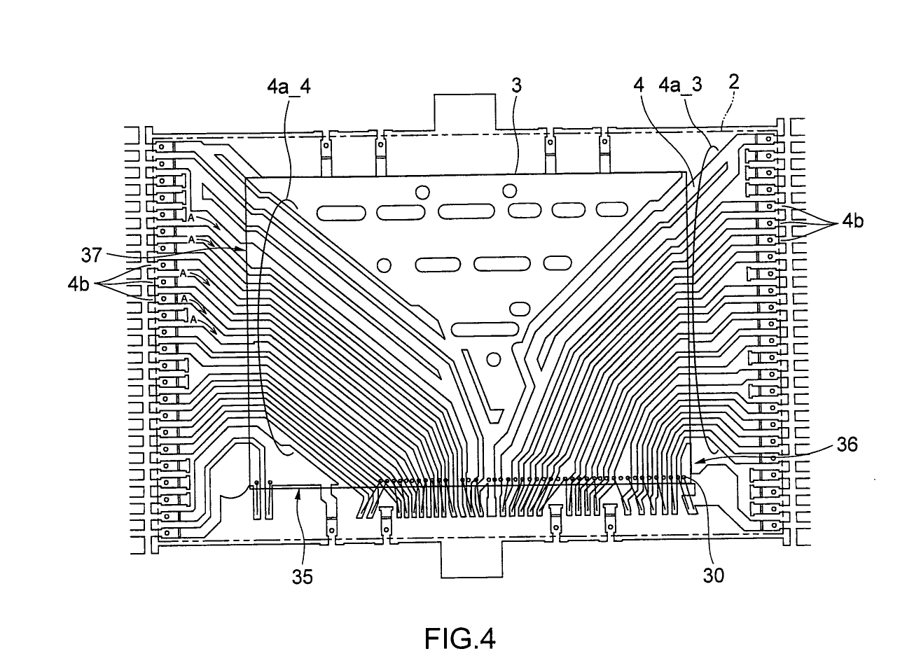

FIG. 4 is a plan view showing another example of a configuration of the inner lead 4a. The plurality of inner leads 4a are electrically connected to the bonding pad 30 of the semiconductor chip 3. The bonding pad 30 is collectively formed on one side portion 35 of the semiconductor chip 3. An inner lead 4a_3, which is a part of the plurality of inner leads 4a, is extended to a side portion 36 different from the side portion 35 having the bonding pad 30 provided thereon of the semiconductor chip 3. Subsequently, the inner lead 4a_3 is connected to the outer lead 4b projecting from a side portion 36 side to the outside of the resin 2.

An inner lead 4a_4, which is a part of the plurality of inner leads 4a, is extended to a side portion 37 different from the side portion 35 of the semiconductor chip 3. Additionally, the inner lead 4a_4 is connected to the outer lead 4b projecting from a side portion 37 side to the outside of the resin 2.

As described above, in the embodiment, the inner lead 4a is extended toward the side portion different from the side portion having the bonding pad 30 provided thereon of the semiconductor chip 3. In the resin sealing process, a gap at least with a thickness of the inner lead 4a exists between the upper mold and a lower mold. For example, the thickness of the inner lead 4a is approximately 0.1 millimeter. Hence, even though the semiconductor chip 3 is larger than the width between the steps 13, the resin 2 can flow between the inner leads 4a through this gap as shown with an arrow A of FIGS. 3 and 4 in the resin sealing process.

The semiconductor device according to the embodiment can produce the following effects.

(1) Attachment of the second resin portion 2b to the protruding portion 18 between the outer lead 4b and the inner lead 4a can be suppressed while covering the non-mounting surface F2 of the inner lead 4a with the second resin portion 2b. (1-a) Since the non-mounting surface F2 is covered with the second resin portion 2b, a possibility that the non-mounting surface F2 gets contact with the conductive body around the semiconductor device 10 can be suppressed. In addition, (1-b) since the second resin portion 2b does not exist on the protruding portion 18, there is little possibility that the end of the second resin portion 2b is chipped even if the first resin portion 2a comes away from the anchor hole 9. This leads to suppression of the appearance defect of the semiconductor device 10, and of occurrence of dust and particles. (1-c) Since the non-mounting surface F2 of the inner lead 4a is dented deeper than the protruding portion 18, a thickness of the whole semiconductor device 10 can be made small while the thickness of the second resin portion 2b is kept to some extent.

(2) The step 13 suppresses the semiconductor chip 3 from blocking the anchor hole 9 at the mounting surface F1 side of the inner lead 4a. Namely, maintaining the gap G between the semiconductor chip 3 and the inner lead 4a enables the resin 2 to flow into the anchor hole 9.

(3) The anchor hole 9 functions as the retaining hole for the first resin portion 2a. As a result of this, even though the outer lead 4b is pushed up in the D2 direction, the first resin portion 2a can be suppressed from coming away from the anchor hole 9.

(4) The projection of the molding die supports the non-mounting surface F2 of the inner lead 4a, and thereby the gap between the molding die and the non-mounting surface F2 can be secured. As a result of this, the resin 2 can be fully flowed also into the non-mounting surface F2 side. Namely, the projection of the molding die secures the gap between the molding die and the non-mounting surface F2 together with the protruding portion 18, and thereby the resin 2 can fully cover the non-mounting surface F2. Since the non-mounting surface F2 is fully covered with the second resin portion 2b, the appearance defect of the semiconductor device 10 can be suppressed. The dent 14 is the dent that has remained in the semiconductor device 10 as the mark of the projection provided in the molding die in the resin sealing process. It turns out that the projection is provided in the molding die because of an existence of the dent 14.

As described above, it turns out that in the embodiment, chips and poor filling of the sealing resin can be suppressed while making small the thickness of the second resin portion 2b as much as possible.

Further, in the embodiment, although it is necessary to change an upper die and a TF die for the TSOP, an existing lower die can be utilized as it is. Hence, since it is not necessary to create the lower die of the molding die, rise of the manufacturing cost of the semiconductor device 10 can be suppressed.

### MODIFIED EXAMPLE

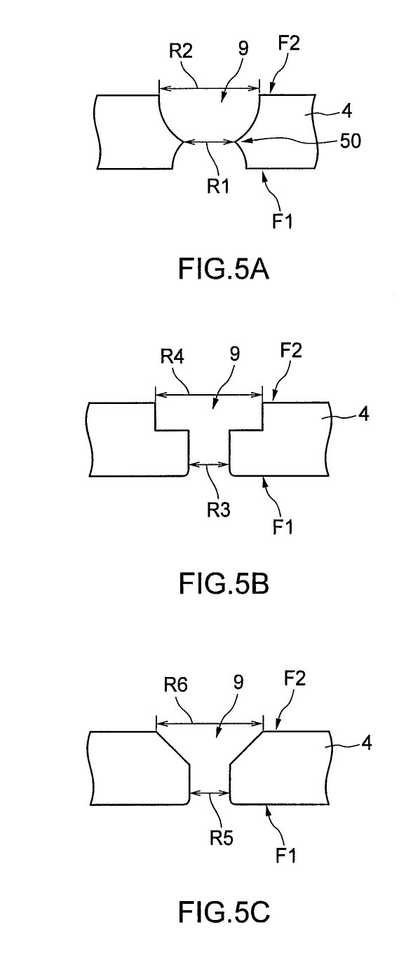

FIGS. 5A to 5C are cross-sectional views showing a modified example of a shape of the anchor hole 9. The shape of the anchor hole 9 is not particularly limited as long as it functions as the retaining hole for the first resin portion 2a. In order to function as the retaining hole for the first resin portion 2a, the anchor hole 9 may be provided with a portion whose opening diameter is smaller than that of the non-mounting surface F2 side.

For example, as shown in FIG. 5A, a shape of the cross section of the anchor hole 9 may be the one made by overlapping two hanging bells or two hemispheres. In this case, a projecting portion 50 is formed on an inner surface of the anchor hole 9 of any portion between the mounting surface F1 and the non-mounting surface F2. Hence, a diameter R1 of the anchor hole 9 of the portion between the mounting surface F1 and the non-mounting surface F2 is smaller than an opening diameter R2 of the anchor hole 9 of the non-mounting surface F2 side. As a result of this, the anchor hole 9 can function as the retaining hole for the first resin portion 2a. The anchor hole 9 shown in FIG. 5A can be formed by performing wet etching of the lead frame 4 from the surfaces F1 and F2.

For example, as shown in FIG. 5B, the cross section of the anchor hole 9 may be substantially T-shaped. In this case, an opening diameter R3 of the mounting surface F1 side is smaller than an opening diameter R4 of the non-mounting surface F2 side. As a result of this, the anchor hole 9 can function as the retaining hole for the first resin portion 2a. The anchor hole 9 shown in FIG. 5B can be formed by punching and coining.

Further, for example, as shown in FIG. 5C, the cross section of the anchor hole 9 may be substantially Y-shaped. In this case, an opening diameter R5 of the mounting surface F1 side is smaller than an opening diameter R6 of the non-mounting surface F2 side. As a result of this, the anchor hole 9 can function as the retaining hole for the first resin portion 2a. The anchor hole 9 shown in FIG. 5C can also be formed by punching and coining.

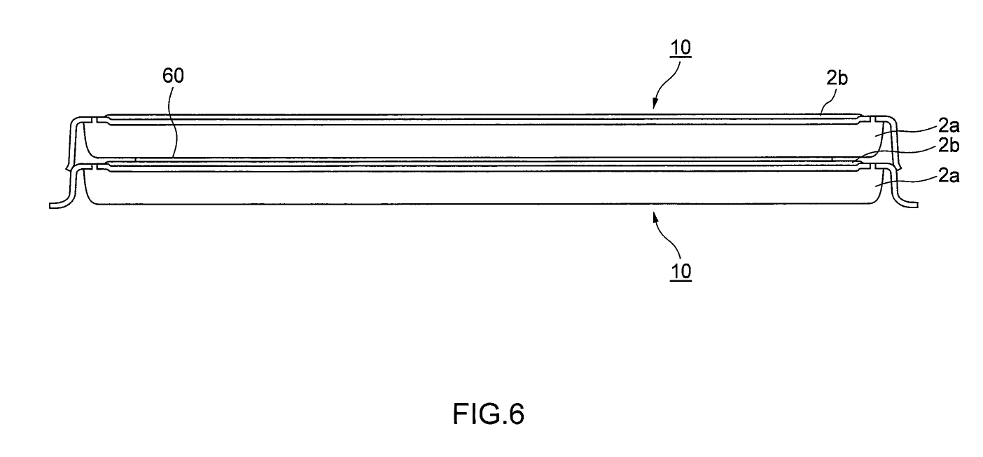

FIG. 6 is a view showing a structure (package-on-package (PoP) structure) made by stacking a plurality of semiconductor devices 10 according to the embodiment. Adhesive films 60 have made the stacked plurality of semiconductor devices 10 adhere to each other.

According to the embodiment, since the thickness of the second resin portion 2b of the non-mounting surface F2 side is made small, when the plurality of semiconductor devices 10 are stacked, a height (thickness) of the whole devices after stacking becomes lower (smaller) than a conventional one.

In addition, in the embodiment, the thickness of the semiconductor device 10 is made smaller than the conventional one by making small the thickness of the second resin portion 2b. However, the thickness of the first resin portion 2a may be made larger only for the thickness of the second resin portion 2b that has been made smaller without changing the thickness of the whole semiconductor device 10. In this case, since the thickness of the first resin portion 2a becomes larger, the stacked number of the semiconductor chips 3 resin-sealed within the each semiconductor device 10 can be increased.

### (Comparison Between the Embodiment and an SON-Type Package)

As a semiconductor package in which only one side of the lead frame 4 is resin-sealed, there is a small outline no-lead (SON) type package. However, in the SON type package, only a mounting portion of an electrode used for mounting on a glass epoxy substrate is exposed to an outside of the semiconductor device. Additionally, this electrode is soldered to the glass epoxy substrate. Hence, when the semiconductor device thermally expands or thermally contracts due to temperature change after the semiconductor device is mounted, a stress is applied to the electrode and a soldered portion depending on a difference between thermal expansion coefficients of the semiconductor device and the glass epoxy substrate, and thereby there occurs a possibility that the electrode or the soldered portion fractures.

Meanwhile, the TSOP type semiconductor package as in the embodiment is soldered to a glass epoxy substrate through the gull-wing-shaped outer lead 4b. Hence, a stress caused by a difference between thermal expansion coefficients of the semiconductor device and the glass epoxy substrate is absorbed by the outer lead 4b. Hence, there is little possibility that a soldered portion fractures. As a result of this, the TSOP type semiconductor package can be increased in package size compared with the SON type semiconductor package. Namely, a larger-sized semiconductor chip can be used for the TSOP type semiconductor package compared with the SON type semiconductor package. In addition, since the TSOP type semiconductor package is provided with the gull-wing-shaped outer lead 4b, the PoP structure in which the semiconductor chips are stacked can be easily configured compared with the SON type semiconductor package.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
an inner lead including a first surface and a second surface opposite to the first surface;
a semiconductor chip mounted on the first surface;
a first resin portion sealing the semiconductor chip on the first surface,
a second resin portion on the second surface, and
an outer lead connected to the inner lead, and configured to project outside from the first and second resin portions, wherein
a width of the second resin portion in a first direction where the outer lead projects is smaller than that of the first resin portion in the first direction.

2. The device according to claim 1, wherein the inner lead includes a hole which is covered with the first resin portion on a side of the first surface and which is exposed from the second resin portion on a side of the second surface.

3. The device according to claim 2, wherein
the hole is opened so as to widen from the first surface toward the second surface, and
the first resin portion is embedded in the hole.

4. The device according to claim 2, wherein
the hole has a projecting portion on an inner surface thereof, and
the first resin portion is embedded in the hole.

5. The device according to claim 3, wherein
the hole has a projecting portion on an inner surface thereof, and
the first resin portion is embedded in the hole.

6. The device according to claim 1 further comprising:
a dent in which the second resin portion is not provided on the second surface or in which the second resin portion is shallow compared with the second resin portion of a periphery thereof.

7. The device according to claim 2 further comprising:
a dent in which the second resin portion is not provided on the second surface or in which the second resin portion is shallow compared with the second resin portion of a periphery thereof.

8. The device according to claim 3 further comprising:
a dent in which the second resin portion is not provided on the second surface or in which the second resin portion is shallow compared with the second resin portion of a periphery thereof.

9. The device according to claim 4 further comprising:
a dent in which the second resin portion is not provided on the second surface or in which the second resin portion is shallow compared with the second resin portion of a periphery thereof.

10. The device according to claim 1, wherein the inner lead is provided with a step between the inner lead and the outer lead so that the outer lead protrudes closer to a second surface side than the inner lead in a boundary portion.

11. The device according to claim 2, wherein the inner lead is provided with a step between the inner lead and the outer lead so that the outer lead protrudes closer to a second surface side than the inner lead in a boundary portion.

12. The device according to claim 3, wherein the inner lead is provided with a step between the inner lead and the outer lead so that the outer lead protrudes closer to a second surface side than the inner lead in a boundary portion.

13. The device according to claim 4, wherein the inner lead is provided with a step between the inner lead and the outer lead so that the outer lead protrudes closer to a second surface side than the inner lead in a boundary portion.

14. The device according to claim 5, wherein the inner lead is provided with a step between the inner lead and the outer lead so that the outer lead protrudes closer to a second surface side than the inner lead in a boundary portion.

15. The device according to claim 10, wherein the step is provided closer to the inner lead side compared with the hole.

16. The device according to claim 2, wherein the resin exists between an opening of the first surface side of the hole and the semiconductor chip.

17. The device according to claim 1, wherein the inner lead is electrically connected to a bonding pad of the semiconductor chip, and the inner lead extends toward a side portion different from a side portion having the bonding pad provided thereon of the semiconductor chip.

18. The device according to claim 1, wherein the device has a COL type package.

19. The device according to claim 1, wherein the device has a TSOP type package.
